(19) United States
(12) Patent Application Publication
(10) Pub. No.: US 2024/0178817 A1
(43) Pub. Date: May 30, 2024

(54) FILTERING DEVICE AND METHOD

(71) Applicant: STMicroelectronics France, Montrouge (FR)

(72) Inventors: Eric Andre, Hurtieres (FR); Lionel Vogt, La Rochette (FR)

(21) Appl. No.: 18/520,167

(22) Filed: Nov. 27, 2023

(30) Foreign Application Priority Data
Nov. 28, 2022 (FR) 2212378

(51) Int. Cl. H03H 11/04; H03K 3/037; H03K 17/687; H04B 1/04

(52) U.S. Cl. CPC H03H 11/04; H03K 3/037; H03K 17/6871; H04B 1/04

(57) ABSTRACT

In embodiments, a radio frequency transmitter comprising at least one filtering circuit is provided. The filtering circuit includes a series/parallel shift register comprising a binary input and N binary outputs, with N being an integer greater than or equal to OSR, OSR being an integer greater than or equal to 2. The binary outputs ranging from 0 to N−1, the register receiving a binary data signal at a data frequency on its input and implementing shifts on the N binary outputs at a frequency equal to a multiplier of the data frequency and OSR. The filtering circuit further comprising a first circuit defined by N coefficients Cᵢ. For each non-zero coefficient Cᵢ, a signal determined by the coefficient Cᵢ and by the corresponding one of the binary outputs. The filtering circuit further comprising and an adder circuit delivering an output equal to the sum of analog signals.

### CROSS-REFERENCE TO RELATED APPLICATIONS

This application claims the priority benefit of French Patent Application No. 2212378 filed on Nov. 28, 2022, which application is hereby incorporated by reference herein in its entirety.

### TECHNICAL FIELD

The present disclosure generally concerns signal filtering devices, circuits, and methods.

### BACKGROUND

Electronic devices or circuits configured to transmit a wireless signal, for example, a radio frequency signal, that is a signal having a carrier frequency in the range of radio frequencies, for example, from 1 GHz to 120 GHz, are known.

According to a targeted application, for example, defined by a standard, all the power of the signal transmitted by these devices has to be within a first given frequency range or at least a certain percentage of the power of the signal transmitted by these devices has to be within a second given frequency range, the second range being narrower than the first one.

The compliance with the transmission conditions as concerns the power of the transmitted signal requires implementing a filter which raises many issues, for example, when the signal is transmitted in the 60-GHz band.

### SUMMARY

There exists a need to overcome all or part of the disadvantages of known filtering circuits, devices, and methods, for example, when the filtering is implemented to shape a radio frequency signal to be transmitted, for example, in the 60-GHz band.

An embodiment overcomes all or part of the disadvantages of known filtering circuits, devices, and methods, for example, when the filtering is implemented to shape a radio frequency signal to be transmitted, for example, in the 60-GHz band.

An embodiment provides a radio frequency transmitter comprising at least one filtering circuit, the at least one filtering circuit comprising: a series/parallel shift register comprising a binary input and N binary outputs Oi, with N being an integer greater than or equal to OSR, OSR an integer greater than or equal to 2, and i being an integer index ranging from 0 to N−1, the shift register being configured to receive a binary data signal at a frequency Fdata on its input and to implement shifts on its outputs Oi at a frequency equal to Fdata*OSR; a first circuit defined by N coefficients Ci and configured to deliver, for each non-zero coefficient Ci, an analog signal SIGi determined by the coefficient Ci and by a binary state of the corresponding output Oi; and an adder circuit configured to deliver an analog output signal of the filtering circuit equal to the sum of analog signals SIGi.

Another embodiment provides a method implemented in a radio frequency transmitter comprising at least one filtering circuit, the method comprising: receiving a binary data signal at a frequency Fdata on a binary input of a series/parallel shift register of the at least one filtering circuit, the shift register comprising N binary outputs Oi, with N being an integer greater than or equal to OSR, OSR an integer greater than or equal to 2, and i being an integer index ranging from 0 to N−1; implementing with the shift register frequency shifts of its outputs Oi at a frequency Fdata*OSR; with a first circuit of the at least one filtering circuit, the first circuit being defined by N coefficients Ci, delivering, for each non-zero coefficient Ci, an analog signal SIGi determined by the coefficient Ci and a binary state of the corresponding output Oi; and delivering, with an adder circuit of the at least one filtering circuit, an analog output signal of the filtering circuit equal to the sum of analog signals SIGi.

According to an embodiment, coefficients Ci are determined by a pulse response h(t) of an interpolation filter, preferably of raised cosine type.

According to an embodiment: for i ranging from 0 to N−1, each coefficient Ci is equal to a coefficient Dp of integer index p equal to i+min, min being a positive or zero integer; each coefficient Dp, with p an integer index ranging from 0 to P−1 and P an odd integer greater than N, is calculated in a recursive manner with the following formula:

$$D p = B p - {Σ}_{j = p - OSR + 1}^{j = p - 1} Dj ,$$

where j is an integer index, Dj is zero if j is negative and is equal to the coefficient Dp with p=j otherwise, and Bp is a coefficient of index p; and each coefficient Bp, with p the integer index ranging from 0 to P−1, is determined by the following formula: Bp=h((2*p−P+1)/(2*OSR)) where h(t) is normalized and centered on t=0.

According to an embodiment, the shift register of the at least one filtering circuit comprises N synchronous latches controlled by a clock signal at a frequency equal to Fdata*OSR/2, the N latches being connected in series by alternating latches active on a first level of the clock signal and latches active on a second level of the clock signal, the outputs Oi corresponding to the outputs of the N latches.

According to an embodiment, the shift register of the at least one filtering circuit further comprises a synchronous D-type flip-flop having a data input coupled, preferably connected, to the series input of the shift register, a synchronization input configured to receive the clock signal, and an output connected to a data input of the first one of the N series-connected latches.

According to an embodiment, the shift register of the at least one filtering circuit comprises N synchronous D-type flip-flops controlled by a clock signal at a frequency equal to Fdata*OSR, the N flip-flops being series-connected, and the outputs Oi corresponding to the outputs of the N flip-flops.

According to an embodiment, the shift register of the at least one filtering circuit comprises N synchronous D-type flip-flops controlled by a clock signal at a frequency equal to Fdata*OSR/2, the N synchronous flip-flops being connected in series by alternating flip-flops active on the rising edges of the clock signal and flip-flops active on the falling edges of the clock signal, and the outputs Oi corresponding to the outputs of the N latches.

According to an embodiment, for each non-zero coefficient Ci: the first circuit of the at least one filtering circuit comprises a number Ki of identical elementary circuits, each having an output configured to deliver: an analog signal S0 when the corresponding output Oi is in a first binary state and coefficient Ci is positive, a signal S1 complementary to signal S0 when the corresponding output Oi is in a second binary state and coefficient Ci is positive, signal S1 when the corresponding output Oi is in the first binary state and coefficient Ci is negative, and signal S0 when the corresponding output Oi is in the second binary state and coefficient Ci is negative; and number Ki is equal to the absolute value of the rounding to an integer value of the product of coefficient Ci by an integer INT identical for all coefficients Ci.

According to an embodiment, the first circuit of the at least one filtering circuit comprises a plurality of identical elementary circuits for each coefficient Ci, the first circuit further comprising a selection circuit configured to select, for each coefficient Ci, Ki elementary circuits among the plurality of elementary circuits and to turn off the non-selected elementary circuits, Ki being zero for the coefficients Ci equal to zero.

According to an embodiment, each elementary circuit receives the same periodic signal and is configured so that signal S0 is in phase with this periodic signal and at the same frequency as this periodic signal.

According to an embodiment: the output of each elementary circuit comprises a first output node and a second output node; each elementary circuit comprises: a first MOS transistor coupling a reference node to a first inner node, a second MOS transistor coupling the reference node to a second inner node, a third MOS transistor coupling the first inner node to the first output node and having a gate configured to receive the periodic signal, a fourth MOS transistor coupling the first inner node to the second output node and having a gate configured to receive a signal in phase opposition with the periodic signal, a fifth MOS transistor coupling the second inner node to the first output node and having a gate configured to receive the signal in phase opposition, and a sixth MOS transistor coupling the second inner node to the second output node and having a gate configured to receive the periodic signal; and for each non-zero coefficient Ci and for each of the Ki elementary circuits of this coefficient Ci, the first and second transistors are controlled from the corresponding output Oi, or in phase opposition with respect to each other.

According to an embodiment: the transmitter comprises two filtering circuits configured to deliver their output signals to a same node coupled to an antenna of the transmitter; the input of the shift register of a first one of the two filtering circuits receives a first binary data signal at frequency Fdata; and the input of the shift register of a second one of the two circuits receives a second binary data signal at frequency Fdata.

According to an embodiment: the transmitter comprising at least one local oscillator configured to deliver a first periodic signal and a second periodic signal in quadrature with the first periodic signal; the same periodic signal received by the elementary circuits of the first filtering circuit is the first periodic signal; and the same periodic signal received by the elementary circuits of the second filtering circuit is the second periodic signal.

According to an embodiment, the transmitter is configured to transmit in the 60-GHz band.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 illustrates an example of the spectral distribution of the power of a transmitted radio frequency signal and the spectral response of an example of a filter;

FIG. 2 illustrates an example of the spectral distribution of the power of a transmitted radio frequency signal and the spectral response of another example of a filter;

FIG. 3 illustrates, in two very simplified views A and B, an example of the implementation of a filter;

FIG. 4 illustrates, in two very simplified views A and B, an embodiment of a filter;

FIG. 5 shows in the form of blocks a more detailed example of an embodiment of the filter or FIG. 4;

FIG. 6 shows in the form of blocks a more detailed example of an alternative embodiment of the filter of FIG. 4;

FIG. 7 shows in the form of blocks an example of embodiment of a portion of a circuit of FIGS. 5 and 6;

FIG. 8 shows in the form of blocks an example of embodiment of a portion of a circuit of FIG. 7; and

FIG. 9 is a block diagram of an example of embodiment of a radio frequency transmitter.

### DETAILED DESCRIPTION OF EMBODIMENTS

Like features have been designated by like references in the various figures. In particular, the structural or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made, unless specified otherwise, to the orientation of the figures.

Unless specified otherwise, the expressions “around,” “approximately,” “substantially” and “in the order of” signify within 10%, and preferably within 5%.

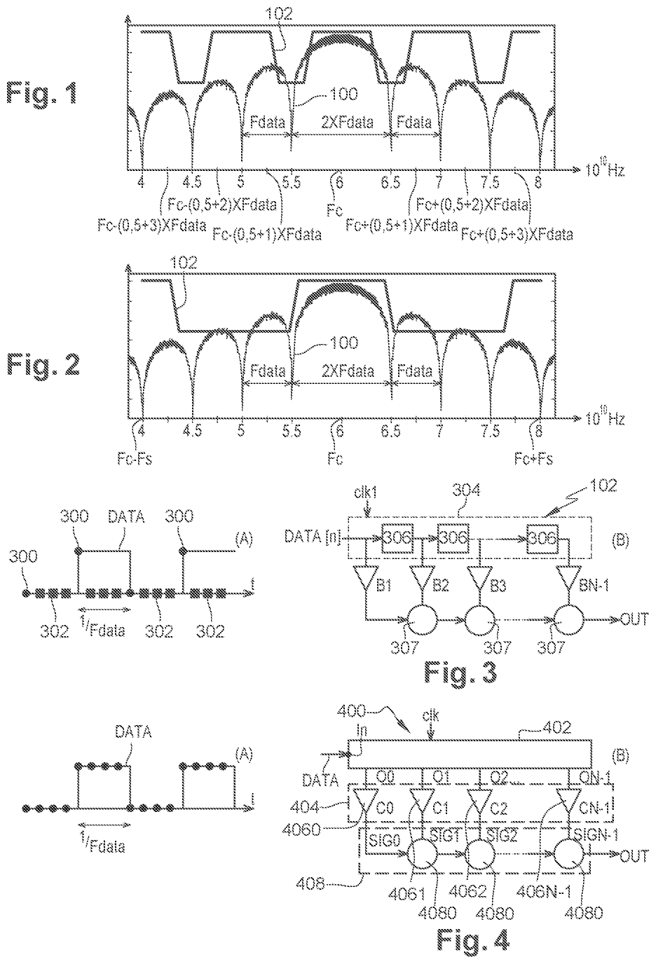

FIG. 1 illustrates an example of spectral distribution 100 of the power of a transmitted radio frequency signal, and the spectral response 102 of an example of a filter.

More particularly, in this example, FIG. 1 illustrates the spectral distribution 100 of the power of a radio frequency signal having a carrier frequency Fc equal to 60 GHz, modulated in QPSK (“quadrature phase shift keying”) with a data frequency Fdata equal to 5 GHz. Further, in this example, filter 102 is a digital filter operating at a frequency Fs equal to twice Fdata. In other words, the oversampling rate OSR of the signal to be filtered, which corresponds to the ratio Fs/Fdata, is here equal to 2. Filter 102 is, for example, an interpolation filter, for example, a low-pass finite impulse response filter.

As can be seen in FIG. 1, the power 100 of the transmitted signal exhibits a main lobe centered on Fc and having a width equal to twice Fdata, and secondary lobes centered on Fc−(0.5+m)*Fdata and Fc+(0.5+m)*Fdata and having a width equal to Fdata, with m a positive integer index. In FIG. 1, only the secondary lobes corresponding to m equal to 1, 2, or 3 are shown.

Filter 102 is here designed so that 99% of power 100 is in a frequency range from 56.5 GHz to 62.5 GHz, considering that 100% of the transmitted power ranges from 42.5 GHz to 77.5 GHz. The response of digital filter 102 centered on frequency Fc is defined on a frequency band having a width equal to Fs. However, the filter's response around frequency Fc can also be found around frequencies equal to Fc−m*Fs and Fc+m*Fs. As an example, filter 102 is of raised cosine type.

As illustrated by FIG. 1, certain secondary lobes, that is, the secondary lobes corresponding to m equal to 1 and m equal to 2, are not sufficiently filtered, whereby more than 1% of the power of the transmitted signal is transmitted at frequencies outside of the range from 56.5 GHz to 62.5 GHz.

FIG. 2 illustrates an example of spectral distribution 100 of the power for the same example of the transmitted signal as in FIG. 1, and the spectral distribution 102 of the same example of the filter as in FIG. 1, with the difference that, in FIG. 2, the oversampling rate OSR of the transmitted signal is equal to 4.

In other words, in FIG. 2, the frequency Fs of digital filter 102 is equal to 20 GHz in this example where Fdata is equal to 5 GHz. As in FIG. 1, the response of digital filter 102 centered on frequency Fc can also be found around frequencies equal to Fc−m*Fs and Fc+m*Fs. However, in the example of FIG. 2, frequency Fs is doubled with respect to the example of FIG. 1.

Thus, conversely to what has been described in relation with FIG. 1, in the example of FIG. 2, the secondary lobes are sufficiently filtered for at least 99% of the power of the transmitted signal to be in the range from 56.5 GHz to 62.5 GHz.

FIGS. 1 and 2 show that a digital interpolation filter operating with an oversampling rate OSR at least equal to 4 enables to concentrate the power of the transmitted signal in a frequency range centered on frequency Fc, so that at least a given percentage of the power of the transmitted signal is transmitted in this frequency band, for example, so that at least 99% of the power of the transmitted signal is in the range from 56.5 GHz to 62.5 GHz in the example of FIG. 2.

FIG. 3 illustrates, in two very simplified views A and B, an example of implementation of the filter 102 of FIGS. 1 and 2, with an oversampling rate OSR equal to 4.

View A (on the left-hand side in FIG. 3) shows the time variation of a binary data signal DATA. Signal DATA thus corresponds to a succession of bits, the state of each bit being held for a duration equal to 1/Fdata. In other words, signal DATA is a binary signal at frequency Fdata.

Points 300 (on the left-hand side in FIG. 3) represent an example of sampling of signal DATA at a frequency equal to Fdata.

To oversample signal DATA at a frequency Fs equal to OSR*Fdata, with OSR equal to 4 in this example, a known solution comprises adding samples 302 introducing no energy into signal DATA and which do not modify the frequency distribution of signal DATA. These samples 302, represented by squares in FIG. 3, do not correspond to a sampling of the real binary value of signal DATA. In other words, samples 302 corresponding to a zero voltage of signal DATA are added. In the example of FIG. 3 where OSR is equal to 4, 3 samples 302 having a zero energy are added after each sample 300, to obtain samples 300, 302 of signal DATA at a frequency equal to OSR*Fdata, or, in other words, a signal DATA[n] oversampled at frequency Fdata*OSR.

View B (on the right-hand side in FIG. 3) schematically shows an example of the implementation of digital filter 102 in the case where filter 102 receives signal DATA[n], that is, the samples 300, 302 of signal DATA, at frequency Fs=OSR*Fdata. In the example of FIG. 3, interpolation filter 102 comprises N coefficients Bi, with i an integer index ranging from 0 to N−1.

Filter 102 comprises a shift register 304 configured to receive the samples 300, 302 of signal DATA, that is, to receive signal DATA[n], at frequency Fs.

Shift register 304 is synchronized on a clock signal clk having a frequency equal to frequency Fs.

Shift register 304 comprises delay elements 306, for example, N elements 306, connected in series. In other words, each element 306 has its input connected to the output of the preceding element 306 and has its output connected to the input of the element 306 following it. Each delay element 306 is synchronized on signal clk1. Each delay element 306 is configured to update its output at frequency Fs, for example, at each rising edge or at each falling edge of signal clk1, then to keep constant the level of its output until the next update of its output. Thus, samples DATA[n] propagate in register 304 at frequency Fs.

Shift registers 304 comprise N outputs that are applied N respective coefficients Bi, with i an integer ranging from o to N−1. The signals obtained by applying the N coefficients Bi to the N corresponding outputs of shift register 304 are then added (blocks 307 in FIG. 3) to obtain an output signal OUT of filter 102.

A problem of the implementation described in relation to FIG. 3 is that signal DATA is a binary signal only taking two levels or states, that is, a zero voltage and a positive voltage, corresponding to two binary values ‘1’ and ‘0’. Thus, each sample 300, 302 corresponds to a bit at ‘1’ or ‘0’. Now, applying a coefficient Bi to a bit 300, 302 amounts to delivering a signal A when bit 300, 302 is in a first binary state, for example, ‘1’, and to delivering a complementary signal—A when bit 300, 302 is in a second binary state, for example, ‘0’. To introduce no energy into the signal DATA to be filtered, that is, to avoid creating a non-zero DC component (DC) on the output OUT of filter 102, the application of a coefficient Bi to a bit 302 would have to amount to delivering a signal of zero value, which raises many issues. Indeed, this complexifies the implementation of filter 102.

For example, this imposes providing different processings between sample 300 and sample 302, which is undesirable.

For example, this imposes determining for each sample DATA[n] whether the sample corresponds to a bit DATA at value ‘1’, to a bit DATA at value ‘0’, or to a sample 302 corresponding to an energy zero of signal DATA. It thus becomes necessary to code each sample DATA[n] with a three-state digital signal. For example, in the case where the application of coefficients Bi to samples DATA[n] results in the obtaining of a digital signal OUT over a plurality of bits, this complexifies a subsequent step of digital-to-analog conversion of signal OUT. For example, in the case where the application of coefficients Bi to samples DATA[n] is performed simultaneously or subsequently to the digital-to-analog conversion, the digital-to-analog conversion is no longer intrinsically linear, conversely to the case of a 1-bit digital-to-analog converter.

To overcome the disadvantages of implementation and operation of known interpolation filters, it is here provided to oversample a binary signal DATA at a frequency Fs=OSR*Fdata, with OSR at least equal to 2, to apply an interpolation filter to the obtained samples but by implementing the oversampling with no addition of samples 302 corresponding to a zero energy of signal DATA. Instead, signal DATA at frequency Fdata is sampled at frequency Fs equal to OSR times Fdata, whereby, for each bit of signal DATA, that is, for each period of duration 1/Fdata of signal DATA, the sampled signal comprises a number OSR of samples having the same binary value ‘1’ or ‘0’ determined by the binary state of the bit of signal DATA. The coefficients Bi of the interpolation filter 102 described in relation to FIG. 3 are thus no longer adapted to the signal DATA and thus oversampled, and new coefficients Ci are thus accordingly recalculated to obtain the same response. These coefficients Ci are, for example, calculated based on the known coefficients Bi.

As will be described hereafter in relation to a specific example of interpolation filter and implementation, the solution provided herein enables to decrease in the surface area and the complexity of the circuit implementing the filter with respect to the implementation of FIG. 3 and thus be compatible with the propagation of radio frequency signals in the filter.

FIG. 4 illustrates, in two very simplified views A and B, an embodiment of an interpolation filter 400. Filter 400 is for example, configured to deliver the same signal OUT as the filter 102 of FIG. 3, or, in other words, to have the same response as the interpolation filter 102 used with signal DATA oversampled at an OSR rate equal to 4 by addition of samples 302 of zero energy. For example, device 400 is implemented in a radio frequency transmitter, not illustrated in FIG. 4.

View A (on the left-hand side in FIG. 4) shows the time variation of binary data signal DATA corresponding to a succession of bits at frequency Fdata. Points 400 show the samples of signal DATA oversampled at Fs=OSR*Fdata, with OSR equal to 4 in this example.

View B (on the right-hand side in FIG. 4) schematically shows an embodiment of filtering device 400 in the case where signal DATA is sampled at frequency Fs. Similarly to filter 102, which is defined by N coefficients Bi, filter 400 is defined by N coefficients Ci. As described hereafter, to obtain the same response OUT with the filter of FIG. 4 as that of FIG. 3, the number N of coefficients Ci is smaller than the number N of coefficients Bi. Further, the implementation of the N coefficients Ci is much more compact than the implementation of the N coefficients Bi. Although this will be described as a specific example of an interpolation filter and implementation of the coefficients, these advantages can be found with other examples of interpolation filters or other implementations of the coefficients.

The filtering device, or filter, 400 comprises a shift register 402. Shift register 402 is of series/parallel type. Register 402 thus comprises a series input In and a plurality N of parallel outputs Oi, with i an integer index ranging from 0 to N−1 and N a positive integer greater than or equal to OSR.

Input In is a binary input, that is, it is configured to receive a binary signal, that is, signal DATA. Each output Oi is a binary output, that is, it is configured to deliver a binary signal. In the following description, there is designated with the same reference Oi an output of register 402 and the binary signal or bit present on this output. In the present description, a binary signal can take two levels or states, for example, a zero voltage and a positive voltage, corresponding to two binary values ‘0’ and ‘1’. In other words, a binary signal corresponds to a succession of bits, the bits following one another at a given frequency, for example, at frequency Fdata in the case of signal DATA.

Shift register 402 is configured to implement shifts at frequency Fs. In other words, shift register 402 is configured so that each output Oi of register 402 (except for output O0) delivers the bit of output Oi−1 with a delay equal to 1/(Fdata*OSR), and that outputs Oi are updated at frequency Fs. Still, in other words, register 402 is configured to transmit each bit of the signal DTA received on its input In, on its outputs Oi with multiple delays of 1/(Fdata*OSR) and determined, for each output Oi, by the index i of this output. For example, each output Oi receives the binary state present on input In of register 402 with a delay equal to Hi*(1/(Fdata*OSR)), where Hi is an integer determined by i and, preferably, Hi+1=1+Hi. Still, in other words, register 402 is configured so that at each switching of each output Oi, output Oi remains in the same binary state for a duration 1/(Fdata*OSR) from this switching.

According to an embodiment, register 402 comprises level-active synchronous latches. The synchronous latches, preferably N synchronous latches, are connected in series. For the shifts in register 402 to be performed at frequency Fs, the latches in series are controlled by a clock signal clk at a frequency Fclk=(OSR/2)*Fdata and the latches are connected in series by alternating latches active on a first level, for example, high, of signal clk, and latches active on a second level, for example, low, of signal clk. Outputs Oi correspond to the outputs of the latches, preferably to the outputs of the N latches in series. In such an embodiment, a synchronous D-type flip-flop may be provided between input In of the register and the first latch of the series connection of the latches. This D flip-flop is synchronized with signal clk, and more particularly on a given type, for example, rising, or falling, of edges of signal clk. Such a D-type flip-flop enables to hold, for each bit of signal DATA, a stable state for a duration 1/Fdata on the input of the first latch of the plurality of latches in series, for example, to avoid problems that may occur when signal DATA is not synchronized with signal clk.

According to another embodiment, shift register 402 comprises a synchronous D-type flip-flop. D flip-flops, preferably N D flip-flops, are series-connected. For the shifts in register 402 to occur at frequency Fs, the flip-flops in series are controlled by a clock signal clk at a frequency Fclk=OSR*Fdata, and are all active on the same type of edge, for example, rising, of signal clk. Outputs Oi correspond to the outputs of the flip-flops, preferably to the outputs of the N flip-flops.

According to another embodiment, shift register 402 comprises synchronous D-type flip-flops, the D flip-flops, preferably N D flip-flops, being series-connected. For the shifts in register 402 to be performed at frequency Fs, the flip-flops in series are controlled by a clock signal clk at a frequency Fclk=(OSR/2)*Fdata and are connected in series by alternating flip-flops active on a first level, for example, high, of signal clk, and flip-flops active on a second level, for example, low, of signal clk. Outputs Oi correspond to the outputs of the flip-flops, preferably to the outputs of the N flip-flops.

The provision of a register 402 where shifts occur at frequency Fs and which is controlled by a signal clk at frequency Fclk=(OSR/2)*Fdata enables to decrease switchings and thus the power consumption and the switching noise with respect to a register 402 where shifts occur at frequency Fs but which is controlled by a signal clk at frequency Fclk=OSR*Fdata. Further, it is simpler to generate and propagate to the elements of register 402 a clock signal at frequency (OSR/2)*Fdata rather than at frequency OSR*Fdata.

The provision of a register 402 comprising N latches in series delivering the N outputs Oi of register 402 enables to decrease the bulk with respect to a register 402 comprising N D flip-flops in series delivering the N outputs Oi of register 402.

As compared with what has been described in relation with FIG. 3, oversampling binary signal DATA at a frequency Fs=OSR*Fdata, with OSR at least equal to 2, and with no addition of samples 302 corresponding to a zero energy of signal DATA, enables to limit the number of switchings of the binary outputs Oi of register 402, in particular when signal DATA remains for a plurality of successive periods 1/Fdata in a binary state corresponding to a sample 300 of non-zero energy.

It should be understood that conversely to register 304 of filter 102 of FIG. 3, register 402 of device 400 does not take as an input In a signal DATA[n] oversampled at Fs=OSR*Fdata by addition of samples 302 at zero energy, but directly binary signal DATA at frequency Fdata. The sampling (or oversampling) of signal DATA at frequency Fs=OSR*Fdata is implemented by register 402.

Device 400 further comprises a circuit 404. Circuit 404 is defined, or determined, by the N coefficients Ci. Circuit 404 is configured to deliver, for each non-zero coefficient Ci, an analog signal SIGi, for example, a current, determined by the coefficient Ci and by a binary state of the output Oi corresponding to this coefficient Ci, that is, the output Oi having the same index i as this coefficient Ci.

As an example, for each non-zero coefficient Ci, circuit 404 comprises a circuit 406i configured to receive the corresponding output Oi and to deliver the signal SIGi determined by the binary state of output Oi and by the coefficient Ci.

As an example, circuit 404 is configured to deliver, for each non-zero coefficient Ci, for example, with the corresponding circuit 406i, analog signal SIGi at a first value proportional or equal to coefficient Ci when output Oi is in a first binary state, for example, state ‘1’, and at a second value proportional or equal to coefficient Ci when output Oi is in a second binary state, for example, state ‘0’. Preferably, the second value is equal at least to the first value.

As an example, circuit 404 is configured to deliver, for each non-zero coefficient Ci, an analog signal SIGi determined by the coefficient Ci, by a binary state of output Oi corresponding to this coefficient Ci, and further by a periodic signal SIGLO (not shown in FIG. 4). As an example, circuit 404, for example, each circuit 406i, receives periodic signal SIGLO, for example, at frequency Fc. As an example, circuit 404 is then configured to deliver, for each non-zero coefficient Ci, for example, with the corresponding circuit 406i, an analog signal SIGi having a first value proportional, preferably equal, to SIGLO*Ci when output Oi is in a first binary state, for example, state ‘1’, and having a second value proportional, preferably equal, to −SIGLO*Ci when output Oi is in a second binary state, for example, state ‘0’.

Device 400 further comprises an adder circuit 408. Circuit 408 is configured to deliver an analog output signal OUT of filtering circuit 400 which is equal to, or determined by, the sum of analog signals SIGi. For example, circuit 408 may implement a function of impedance matching of output OUT. For example, circuit 408 is configured to receive the output signals SIGi of circuit 404.

As an example, circuit 408 comprises a node configured to receive all the analog signals SIGi and to deliver analog signal OUT, each signal SIGi for example, corresponding to a current.

As an alternative example, adder circuit 408 comprises a plurality of circuits 4080 configured to receive signals SIGi and add them. For example, each circuit 4080 is configured to receive a signal SIGi, to add it to the sum of signals SIG0 to SIGi−1 by the previous circuit 4080 and to deliver the sum of signals SIG0 to SIGi to the next circuit 4080 as shown in FIG. 4, view (B), circuit 4080 receiving the signal SIGN−1 delivering signal OUT. For example, circuits 4080 share a same node common to all the circuits 4080 having signals SIGi added thereon and having output signal OUT available thereon. For example, each circuit 4080 may implement an impedance matching function between the received signal SIGi and the output signal OUT of circuit 408.

As another alternative example, circuit 408 may be implemented by a radio frequency impedance matching network receiving as distributed inputs signals SIGi and delivering output OUT, the forming of such a radio frequency impedance matching network by means of coupled inductances (transformers) or transmission lines being within the abilities of those skilled in the art.

When filter 400 is an impulse response filter and it delivers analog signal OUT directly based on binary outputs Oi, that is, based on the binary samples of signal DATA sampled at Fs, device 400 is for example, called digital-to-analog conversion finite impulse response filter (FIRDAC filter). When, further, signal OUT, for example, each signal SIGi, is determined by or depends on periodic signal SIGLO, filter 400 is, for example, called mixing FIRDAC filter.

According to an embodiment, the N coefficients Ci of device 400 are determined by the impulse response h(t) of an interpolation filter, for example, of raised cosine type.

An example of an embodiment of the determination of coefficients Ci will now be described in relation with the above table Table 1, in the case where one considers, as an example, the impulse response h(t) defined by the following formula:

$$h ( t ) = \{ \begin{matrix}\frac{sin ( π t / T )}{( π t / T )} \cdot \frac{π}{4} si \frac{t}{T} = ∓ \frac{1}{2 β} \\ \frac{sin ( π t / T )}{( π t / T )} \cdot \frac{cos ( πβ t / T )}{1 - {( 2 β t / T )}^{2}} sinon\end{matrix} ,$$

with β a roll-off factor in the range from 0 to 1, and T the period of signal DATA equal to 1/Fdata.

The following response h(t) is normalized, that is, its maximum amplitude is equal to 1, and is further centered on t=0.

P coefficients Bp can then be calculated from response h(t), by using the following formula: Bp=h((2*p−P+1)/(2*OSR)), with p an integer index ranging from 0 to P−1, P a positive odd integer greater than or equal to N and OSR the oversampling rate.

In the considered example, P is equal to 25 and roll-off factor β is equal to 0.65, although the present disclosure is not limited to this specific example. Coefficients Bp are listed in column col1 of table Table 1, and their decimal values are listed in column col2 of table Table 1. In this example, OSR is equal to 4.

TABLE 1

| col1 | col2 | col3 | col4 | col5 | col6 | col7 |
|---|---|---|---|---|---|---|
| B0 | 0.00 | 0 | D0 | 0.00 | | |
| B1 | 0.00 | 0 | D1 | 0.00 | | |
| B2 | 0.00 | 0 | D2 | 0.00 | | |
| B3 | 0.00 | 0 | D3 | 0.00 | | |
| B4 | 0.00 | 0 | D4 | 0.00 | | |
| B5 | −0.03 | −1 | D5 | −0.03 | C0 | −1 |
| B6 | −0.08 | −2 | D6 | −0.05 | C1 | −1 |
| B7 | −0.09 | −2 | D7 | −0.01 | C2 | 0 |
| B8 | 0.00 | 0 | D8 | 0.09 | C3 | 2 |
| B9 | 0.24 | 6 | D9 | 0.21 | C4 | 5 |
| B10 | 0.58 | 14 | D10 | 0.29 | C5 | 7 |
| B11 | 0.88 | 21 | D11 | 0.29 | C6 | 7 |
| B12 | 1.00 | 24 | D12 | 0.21 | C7 | 5 |
| B13 | 0.88 | 21 | D13 | 0.09 | C8 | 2 |
| B14 | 0.58 | 14 | D14 | −0.01 | C9 | 0 |
| B15 | 0.24 | 6 | D15 | −0.05 | C10 | −1 |
| B16 | 0.00 | 0 | D16 | −0.03 | C11 | −1 |
| B17 | −0.09 | −2 | D17 | 0.00 | | |
| B18 | −0.08 | −2 | D18 | 0.00 | | |
| B19 | −0.03 | −1 | D19 | 0.00 | | |
| B20 | 0.00 | 0 | D20 | 0.00 | | |
| B21 | 0.00 | 0 | D21 | 0.00 | | |
| B22 | 0.00 | 0 | D22 | 0.00 | | |
| B23 | 0.00 | 0 | D23 | 0.00 | | |
| B24 | 0.00 | 0 | D24 | 0.00 | | |

Coefficients Dp are then calculated, in a recursive manner from the lowest index p, based on the above coefficients Bp, by using the following formula:

$$Dp = B p - {Σ}_{j = p - OSR + 1}^{j = p - 1} Dj ,$$

where j is an integer index, Dj is zero when j is negative. More particularly, for a given index p, the index j of the sum is an integer ranging from p−OSR+1 to p−1, with Dj null when j is negative. For example, the coefficients Dp are calculated recursively by reusing, to calculate the coefficient Dp of a given index p, at least some of the coefficients Dp (i.e. Dj in the formula above) already calculated for the indexes p of values less than the given index p. Said again another way, in the formula above, Dj=Dp when the indexes j and p are equal and j is positive or null, and Dj is null when j is strictly negative.

Coefficients Dp are listed in column col4 of table Table 1, and their decimal values are listed in column col5.

For example, by reusing the formula above and the example of the table Table 1 where OSR=4:
for p=0, we get:

$$D 0 = B 0 - {\sum }_{j = - 3}^{j = - 1} D j = B 0 - 0 = 0.$$

for p=1, we get:

$$D 1 = B 1 - {\sum }_{j = - 2}^{j = 0} D j = B 1 - D 0 = 0.$$

for p=2, we get:

$$D 2 = B 2 - {\sum }_{j = - 1}^{j = 1} D j = B 2 - D 0 - D 1 = 0.$$

for p=3, we get:

$$D 3 = B 3 - {\sum }_{j = 0}^{j = 2} D j = B 3 - D 0 - D 1 - D 2 = 0.00$$

for p=4, we get:

$$D 4 = B 4 - {\sum }_{j = 1}^{j = 3} D j = B 4 - D 1 - D 2 - D 3 = 0.00$$

for p=5, we get:

$$D 5 = B 5 - {\sum }_{j = 2}^{j = 4} D j = B 5 - D 2 - D 3 - D 4 = - 0.03$$

for p=6, we get:

$$D 6 = B 6 - {\sum }_{j = 3}^{j = 5} D j = B 6 - D 3 - D 4 - D 5 = - 0 \text{.05} .$$

By continuing the calculation of the example given above for p ranging from 7 top 24, those skilled in the art will be able to retrieve the values indicated in column col5.

The N coefficients Ci then correspond to N successive coefficients Dp among the P coefficients Dp. In other words, for i ranging from 0 to N−1, each coefficient Ci equals a coefficient Dp of integer index p equal to i+min, min being an integer.

The number N of coefficients Ci and to which N coefficients Dp correspond the N coefficients Ci, that is, the value of integer min, are for example, determined by a targeted error on the pulse response of the filter with respect to an ideal pulse response. The selection of value N or coefficients Ci (that is, of integer min) is within the abilities of those skilled in the art.

In the example illustrated by table Table 1, min equal to 5 and N equal to 12. Coefficients Ci are listed in column col6 of table Table 1, the decimal value of each coefficient Ci being provided by the cell of column col5 and of the row of coefficient Ci.

The calculation of the decimal values of coefficients Ci is not limited to the example of embodiment described hereabove, and those skilled in the art are capable, based on the pulse response h(t) of an interpolation filter, to calculate the decimal values of coefficients Bi enabling to obtain the targeted response when the filter is applied to samples DATA[n] at frequency Fs obtained from signal DATA and by addition of samples of null energy, and to deduce therefrom the coefficients Ci enabling to obtain the same response when filter 400 is applied to the signal DATA sampled at frequency Fs, with no addition of zero energy sample.

According to an embodiment, rather than using the decimal values of coefficients Ci, coefficients Ci having an integer value are used. The integer value of each coefficient Ci corresponds to the rounding to an integer of the product of the decimal value of coefficient Ci by a positive integer INT identical for all coefficients Ci. Those skilled in the art can determine value INT according to a maximum targeted error between the ideal response of the filter and the real response of filter 400 implemented with integer coefficients Ci. Column col7 of the above table Table 1 illustrates the integer values of coefficients Ci for an example where integer INT is equal to 24.

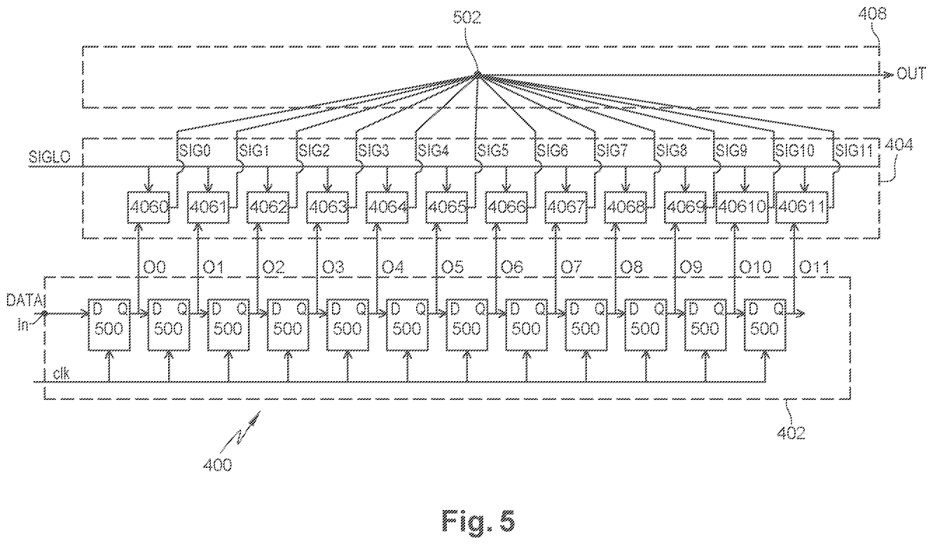

FIG. 5 shows in the form of blocks a more detailed example of an embodiment of the filter 400 of FIG. 4. In this example, filter 400 is implemented with integer coefficients Ci, and, more particularly with the integer coefficients Ci of the above table Table 1. In other examples, not illustrated, filter 400 is implemented with decimal coefficients Ci, for example, with coefficients Ci having their decimal values illustrated by column col5 of the above table Table 1.

FIG. 5 illustrates an embodiment where shift register 402 is implemented based on, or comprises, N D flip-flops 500 connected in series and controlled by a signal clk at frequency Fclk=Fdata*OSR=Fs. Flip-flops 500 are all active on the same type of edge (rising or falling) of signal clk, for example, on a rising edge of signal clk.

Each of the N flip-flops 500 comprises a synchronization input configured to receive signal clk.

Each of the N flip-flops 500 comprises a data input D connected to the Q output of the preceding flip-flop in the connection of N flip-flops 500 in series, except for the first flip-flop which receives signal DATA on its D input. Each of the N flip-flops 500 has its output which delivers a corresponding output Oi of circuit 402. For example, the first of the N flip-flops 500 in series delivers output O0, the second of the N flip-flops 500 in series delivers output O1, and so on until the N-th of the N flip-flops 500 in series which delivers output ON, that is, output O11 in this example.

In this embodiment, for each non-zero coefficient Ci, circuit 404 comprises a circuit 406i configured to receive the corresponding output Oi and to deliver the signal SIGi determined by the binary state of output Oi and by the coefficient Ci. As illustrated in FIG. 5, circuit 404 may also comprise, for each zero coefficient Ci, a corresponding circuit 406i but which is then configured to deliver a zero signal SIGi whatever the state of the output Oi received by this circuit 406i. As an example, each circuit 406i comprises an input configured to receive output Oi. In another example, the circuits 406i corresponding to zero coefficients Ci are omitted.

As an example, and although this is not illustrated in FIG. 5, each circuit 406i may also comprise an input configured to receive a binary signal OCompi complementary to output Oi, that is, a signal OCompi in the high, respectively low level, when output Oi is in the low, respectively high, level. Preferably, signals Oi and OCompi have the same high levels and the same low levels. As an example, each flip-flop 500 is configured to deliver the signal OCompi complementary to the signal Oi delivered by its Q output. In another example, each circuit 406i does not receive signal OCompi.

In the example of FIG. 5, the output signal SIGi of each circuit 406i is further determined by periodic signal SIGLO. Thus, each circuit 406i then comprises an input configured to receive signal SIGLO. As an example, signal SIGLO is a differential signal comprising a component SIGLO+ and a component SIGLO− in phase opposition with component SIGLO+.

In this embodiment, circuit 408 comprises a node 502. As an example, node 502 is connected to an output of each circuit 406i corresponding to a non-zero coefficient Ci, this output of circuit 406i delivering the corresponding signal, for example, a current SIGi. As an alternative example, node 502 is connected to the output of each circuit 406i having the signal SIGi of circuit 406i available thereon. Node 502 is configured to deliver the output signal, for example, a current, OUT of filter 400.

As an alternative embodiment, not illustrated, adder circuit 408 comprises a plurality of circuits 4080 as described in relation with FIG. 4, view (B).

In another alternative example not illustrated, circuit 408 comprises a radio frequency impedance matching network receiving as distributed inputs signals SIGi and delivering output OUT, the forming of such a radio frequency impedance matching network by means of coupled inductances (transformers) or transmission lines being within the abilities of those skilled in the art.

Although there has been described in relation with FIG. 5 an example where filter 400 is a mixing FIRDAC filter, that is, it implements a function of mixing with signal SIGLO, in other examples, not illustrated, this mixing function is omitted, and each circuit 406i then does not receive signal SIGLO.

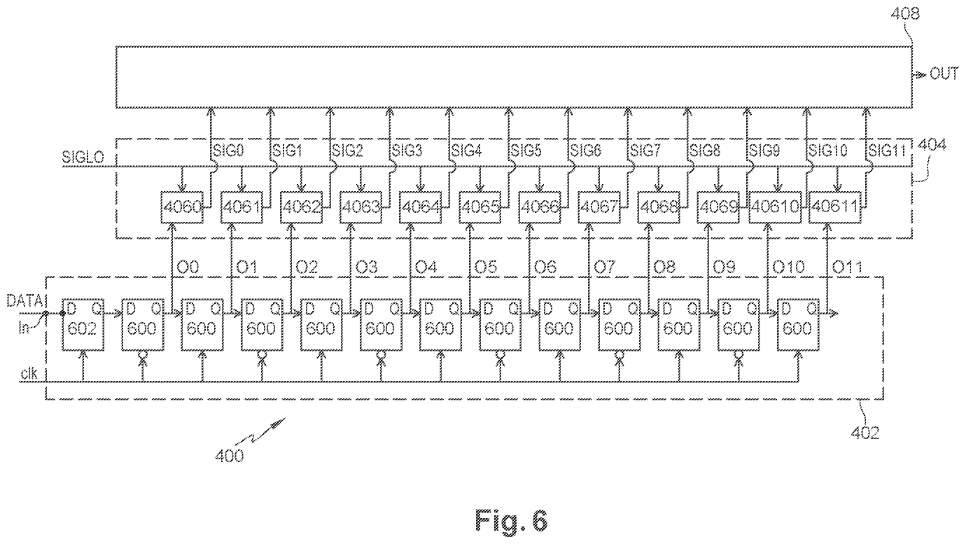

FIG. 6 shows in the form of blocks a more detailed example of an alternative embodiment of filter 400. As in FIG. 5, filter 400 of FIG. 6 is implemented with the integer coefficients Ci of the above table Table 1, although, in other examples, filter 400 is implemented with decimal coefficients Ci. In FIG. 6, circuit 408 has not been detailed, this circuit 408 is for example, implemented as previously described in relation with FIGS. 4 and 5.

The filter 400 of FIG. 6 differs from that of FIG. 5 only by the implementation of shift register 402. Thus, all that has been indicated for the filter 400 of FIG. 5 and which does not directly concern shift register 402 applies to the filter 400 of FIG. 6.

More exactly, in the variant of FIG. 6, shift register 402 is implemented from, or comprises, N series-connected latches 600 controlled by a signal clk at frequency Fclk=Fdata*OSR/2=Fs/2. The N latches are connected in series by alternating latches active on a first level, for example, high, of signal clk, and latches active on a second level, for example, low, of signal clk. As an example, the first of the N latches in series is active on the low level of signal clk. Each of the N latches 600 comprises a synchronization input configured to receive signal clk.

Each of the N latches 600 comprises a data input D connected to the Q output of the preceding latch 600 in the connection of the N latches 600 in series, except for the first latch 600. Each of the N latches 600 has its output which delivers a corresponding output Oi of circuit 402. For example, the first of the N latches 600 in series delivers output O0, the second of the N latches 600 in series delivers output O1, and so on until the Nth of the N latches 600 in series which delivers output ON, that is, output O11 in this example.

As an example, in the embodiment illustrated in FIG. 6, shift register 402 further comprises a synchronous D-type flip-flop 602 between input In of register 402 and the first of the N latches 600 in series. This D flip-flop is synchronized with signal clk, and more particularly on a given type, for example, rising or falling, of edges of signal clk, for example, on a rising edge in the example of FIG. 6. Flip-flop 602 comprises a D input configured to receive signal DATA and a Q output connected to the D input of the first of the N latches 600 in series. In another example not illustrated, this flip-flop 602 may be omitted, the D input of the first of the N latches 600 in series then directly receiving signal DATA.

An advantage of the alternative embodiment of FIG. 6 as compared with the embodiment of FIG. 5 is that register 402 is controlled by a signal clk at frequency Fs/2 rather than by a signal clk at frequency Fs, which decreases the number of switchings, and thus the power consumption, in register 402 although registers 402 have similar outputs Oi.

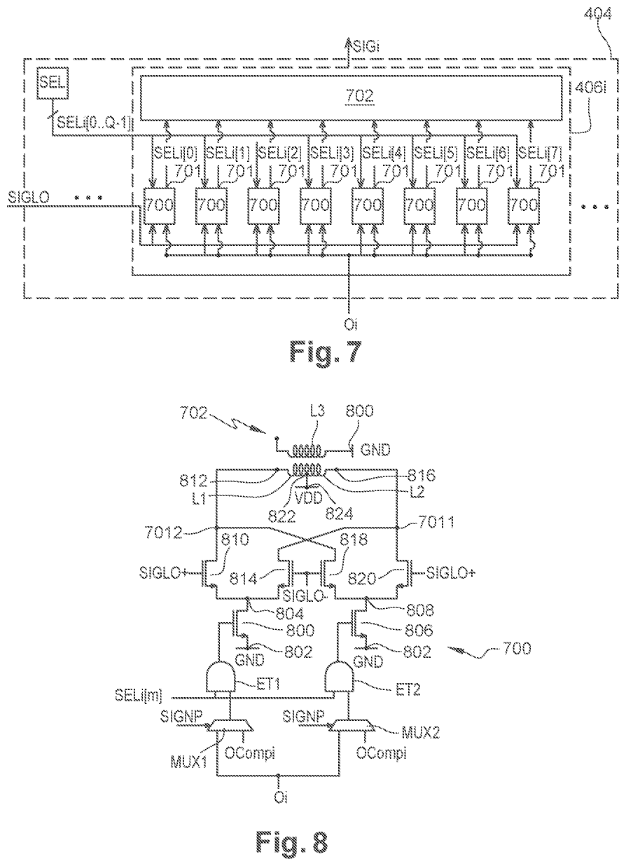

FIG. 7 shows in the form of blocks an example of embodiment of a portion of the circuit 404 of FIGS. 4, 5, and 6. More particularly, FIG. 7 illustrates an example of embodiment of the circuits 406i of circuit 402, a single circuit 406i being shown in FIG. 7.

Circuit 406i comprises a plurality of identical elementary circuits 700.

Each circuit 700 is configured to receive the signal Oi corresponding to the circuit 406i to which it belongs.

Each circuit 700 comprises an output 701 configured to deliver: an analog signal S0 when the output Oi received by this circuit 700 is in a first binary state, for example, state ‘1’ for example, corresponding to a high level of output Oi, and coefficient Ci is positive; a signal S1 complementary to signal S0 when the output Oi received by this circuit 700 is in a second binary state, for example, state ‘0’ for example, corresponding to a low level of output Oi, and coefficient Ci is positive; signal S1 when the output Oi received by this circuit 700 is in the first binary state and coefficient Ci is negative; and signal S0 when the output Oi received by this circuit 700 is in the second binary state and coefficient Ci is negative.

As an example, for each circuit 700, output 701 comprises a single node having the output signal of circuit 700, for example, a current, available thereon. As an alternative example, for each circuit 700, output 701 comprises two nodes between which is available the output signal of circuit 700, for example, a voltage.

The outputs 701 of circuits 700 are connected to an adder circuit 702 of circuit 406i. Circuit 702 is configured to receive the output signals of circuits 700 and to add them to deliver, for example, signal SIGi. As an example, circuit 701 may implement an impedance matching function between the signals S0, S1 that it receives and the output signal that it delivers.

For example, circuit 702 is implemented only by a node connected to all the outputs 701 of circuits 700, outputs 701 then being, for example, current outputs that are directly added on this node. Signal SIGi is then available on this node.

As an alternative example, circuit 702 comprises a radio frequency impedance matching network receiving as distributed inputs the output signals of circuits 700, and outputting the corresponding signal SIGi. The forming of such a radio frequency impedance matching circuit by means of coupled inductances (transformer) or transmission lines is within the abilities of those skilled in the art.

In the embodiment illustrated in FIG. 7, circuit 404 comprises a circuit 406i for each N coefficients Ci of filter 400. Further, circuit 404 comprises a selection circuit SEL configured to select, among the plurality of circuits 700 of circuit 406i, Ki circuits 700, and to turn off the circuits 700 which are not selected. Ki is equal to the absolute value of the integer value of coefficient Ci (see column col17 of the above table Table 1). For example, K0 is equal to 1, and a single circuit 700 is selected from among the Q circuits 700 of circuit 406i. In the illustrated example, each circuit 406i comprises Q circuits 700, with Q equal to 8 in this example. For example, circuit SEL delivers a signal SELi[0 . . . Q−1] to each circuit 406i. Signal SELi[0 . . . Q−1] determines Q signals SELi[m], with m an integer index ranging from 0 to Q−1, delivered to the Q circuits 700 of circuit 406i. For example, each signal SELi[m] indicates to the circuit 700 which receives it whether circuit 700 has to be turned off and then deliver a zero signal on its output 701, or whether circuit 700 has to deliver a non-zero analog signal on its output 701, this analog signal S0 or S1 being determined by the binary state of the corresponding output Oi and the polarity (sign) of the corresponding coefficient Ci.

More particularly, in the example of embodiment illustrated in FIG. 7, filter 400 is a mixing FIRDAC, and each circuit 700 is further configured to receive signal SIGLO. Each circuit 700, when it is selected, is then configured to deliver a signal S0 in phase with signal SIGLO and at the same frequency as signal SIGLO, for example, a current S0 equal to A*SIGLO, and a signal S1 in phase opposition with signal SIGLO, for example, a current S1 equal to −A*SIGLO, with A a coefficient determined by the implementation of circuits 700.

In another example not illustrated, filter 400 does not implement the function of mixing with signal SIGLO, and each circuit 700 does not receive signal SIGLO. Each circuit 700, when it is selected, is then configured to deliver a signal S0, for example, equal to a current Iref, and a signal S1 equal to −S0. In this variant, each circuit 700 for example, corresponds to one or a plurality of controllable constant current sources configured to deliver constant current Iref when circuit 700 has to deliver signal S0, constant current −Iref when circuit 700 has to deliver signal S1, and a zero current when circuit 700 is off.

In the embodiment illustrated in FIG. 7, due to the fact that the Ki circuits 700 of each circuit 406i are selected from among Q circuits 700 of circuit 406i, it is possible to reconfigure filter 400. For example, an impulse response h(t) different from that previously described as an example may be used to calculate the integer values of new coefficients Ci corresponding to this different impulse response, and, for each circuit 406i or coefficient Ci, circuit SEL updates its signal SELi[0 . . . Q−1] to select the number Ki of circuits 700 calculated for this new coefficient Ci.

In an alternative embodiment, not illustrated, filter 400 is not reconfigurable. In this case, circuit 402 does not comprise circuit SEL, and each circuit 406i comprises exactly Ki circuits 700, each delivering signal S0 or S1 according to the binary state of the output Oi it receives. In another example, the circuits 406i corresponding to zero coefficients Ci are omitted. Although this alternative embodiment no longer enables to reconfiguring of filter 400, it has the advantage of being less bulky and consuming less power than the embodiment where filter 400 is reconfigurable.

Referring again to filter 102 of view B of FIG. 3 for which signal DATA is oversampled at frequency Fs by adding samples at zero energy, applying each coefficient Bi to the corresponding output Oi could be implemented by a circuit similar to circuit 404. In this case, each circuit 406i would comprise a number K′i of elementary circuits 700, with K′i the absolute value of the rounding to an integer of the product of coefficient Bi by integer INT, the rounding to an integer of product Bi*INT being illustrated by column col3 of the above table Table 1. Thus, in this example, filter 102 would have required at least 96 circuits 700, whereas the described filter 400 may comprise only 24 circuits 700. The implementation of filter 700 is thus less bulky than that of filter 102. Further, this enables one to ascertain that the propagation of a signal in the filter, at the considered frequencies, is compatible with the physical implementation of the circuit. Indeed, the larger the circuit, the longer the conductive lines (or transmission lines), which may raise an issue. The advantages of the solution provided herein remain valid for other examples where response h(t) or the value INT is different.

FIG. 8 shows in the form of blocks an example of the embodiment of circuit 700 of FIG. 7 and circuit 702 of FIG. 7. In this example, filter 400 implements the mixing function, and circuit 700 is configured to receive signal SIGLO, signal SIGLO being, in this example, a differential signal comprising a component SIGLO+ in-phase and a component SIGLO− in phase opposition. In this example, the output 701 of circuit 700 comprises two nodes 7011 and 7012. The output signal of circuit 700 is available between these two nodes 7011 and 7012.

Circuit 700 comprises a MOS (“Metal Oxide Semiconductor”) transistor 800 coupling a reference node 802 to a node 804. Node 802 is configured to receive a reference voltage, for example, ground GND. Transistor 800 for example, has an N channel and has, for example, its source connected to node 802 and its drain connected to node 804.

Circuit 700 further comprises a MOS transistor 806 coupling node 802 to a node 808. As an example, transistor 806 is identical to transistor 800. As an example, transistor 800 for example, has an N channel and has, for example, its source connected to node 802 and its drain connected to node 808.

Circuit 700 further comprises a MOS transistor 810 coupling node 804 to the output 701 of circuit 700, and, more particularly, to the node 7012 of output 701. Transistor 810 has a gate configured to receive periodic signal SIGLO+. Transistor 810 for example, has an N channel and has, for example, its source connected to node 804 and its drain connected to node 7012.

Circuit 700 further comprises a MOS transistor 814 coupling node 804 to the output 701 of circuit 700, and, more particularly, to the node 7011 of output 701. Transistor 814 has a gate configured to receive periodic signal SIGLO− in phase opposition with signal SIGLO+. Transistor 814 for example, has an N channel and has, for example, its source connected to node 804 and its drain connected to node 7011. As an example, transistors 810 and 814 are identical.

Circuit 700 further comprises a MOS transistor 818 coupling node 808 to node 7012. Transistor 818 has a gate configured to receive periodic signal SIGLO−. Transistor 818 for example, has an N channel and has, for example, its source connected to node 808 and its drain connected to node 7012. For example, transistor 818 is identical to each of transistors 810 and 814.

Circuit 700 further comprises a MOS transistor 820 coupling node 804 to node 7011. Transistor 818 has a gate configured to receive periodic signal SIGLO+. Transistor 820 for example, has an N channel and has, for example, its source connected to node 808 and its drain connected to node 7011. As an example, transistors 818 and 820 are identical.

In this embodiment, the output signal of circuit 700 is available between the nodes 7011 and 7012 of output 701 of circuit 700.

In this embodiment, circuit 702 comprises an inductance Li connected between node 812 and a power supply node 824, and an inductance L2 connected between a node 816 and node 824. Node 824 is, for example, configured to receive a power supply voltage Vdd referenced to reference voltage GND, for example, a positive voltage Vdd. Nodes 812 and 816 are connected to the outputs 701 of all the circuits 700 of a given circuit 406i. For example, node 812 is connected to the nodes 7012 of all circuits 700 of this circuit 406i, for example, via a transmission line connected to inductance L1 and the nodes 7012 of all circuits 700 of this circuit 406i. Symmetrically, node 816 is connected to the nodes 7011 of all circuits 700 of this circuit 406i, for example, via a transmission line connected to inductance L2 and the nodes 7011 of all circuits 700 of this circuit 406i.

Further, in this embodiment, circuit 702 comprises an inductance L3 magnetically coupled to inductances L1 and L2. Inductance L3 has a terminal coupled, for example, connected, to the output of elementary circuit 702, and on which, for example, the output signal SIGi of circuit 702 is available. The other terminal of inductance L3 is for example, coupled, preferably connected, to node 802.

In this embodiment, circuit 702 implements an impedance matching function.

When circuit 700 is one of the Ki circuits 700 of circuit 406i, the transistor 800 of circuit 700 is controlled from the corresponding output Oi, for example, by this output Oi, and transistor 806 is controlled in phase opposition with respect to transistor 800 when coefficient Ci is positive, and, conversely, transistor 806 is controlled from this output Oi, for example, by this output Oi, and transistor 800 is controlled in phase opposition with respect to transistor 806 when coefficient Ci is negative.

In the illustrated embodiment, circuit 700 receives output Oi and the corresponding complementary signal OCompi. As an example, for each output Oi, circuit 402 is configured to also deliver signal OCompi, for example, because signal OCompi is available on an output of the flip-flop or of the latch having another input delivering output Oi, or by means of an inverter receiving signal Oi and delivering signal OCompi. As a variant, for each output Oi, circuit 404 is configured to deliver complementary signal OCompi, for example, by means of an inverter receiving signal Oi and delivering signal OCompi.

In the illustrated embodiment, circuit 700 comprises a routing circuit configured to route signal Oi to the gate of transistor 800 and signal OCompi to the gate of transistor 806 when coefficient Ci is positive, and to route signal OCompi to the gate of transistor 800 and signal Oi to the gate of transistor 806 when coefficient Ci is negative. As an example, the routing circuit comprises two multiplexers MUX1 and MUX2 each having two inputs configured to receive the respective signals Oi and OCompi, and a control input receiving a binary signal SIGNP indicating whether coefficient Ci is positive or negative. The output of multiplexer MUX1, respectively MUX2, is coupled to the gate of transistor 800, respectively 806. For example, signal SIGNP is delivered by a circuit for controlling circuit 404, for example, by circuit SEL.

In the illustrated embodiment, filter 400 is reconfigurable and circuit 700 receives the corresponding signal SELi[m], indicating whether circuit 700 is selected or off. As an example, signal SELi[m] is a binary signal at a high level if circuit 700 is selected, and at a low level otherwise. As an example, circuit 700 then comprises two gates ET1 and ET2, each implementing Boolean function AND. Gate ET1, respectively ET2, has a first input connected to the output of multiplexer MUX1, respectively MUX2, has a second input configured to receive signal SELi[m], and an output coupled, preferably connected, to the gate of transistor 800, respectively 806.

In another embodiment, not illustrated, filter 400 is not reconfigurable and gates ET1 and ET2 are omitted, the output of multiplexer MUX1, respectively MUX2, then being, for example, directly connected to the gate of transistor 800, respectively 806.

In still another embodiment, not illustrated, where filter 400 is not reconfigurable, gates ET1 and ET2 and multiplexers MUX1 and MUX2 are omitted. The gate of transistor 800, respectively 806, then receives, for example, signal Oi, respectively OCompi, if the corresponding coefficient Ci is positive, and signal OCompi, respectively Oi, if the corresponding coefficient is negative.

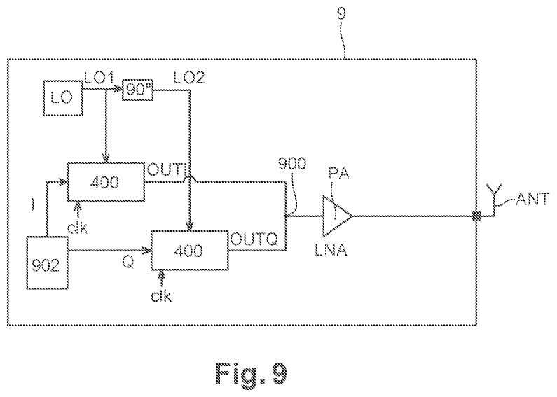

FIG. 9 shows in the form of blocks an example of embodiment of a radio frequency transmitter 9 comprising filter 400. However, filter 400 may be provided in other radio frequency transmitters than that described in relation to FIG. 9.

In this example, transmitter 9 comprises two filters 400, each implementing a mixing function.

The two filters 400 deliver their output signals to the same node 900 of transmitter 9, the output signal OUT of a first one of the two circuits 400 bearing reference OUTI in FIG. 9 and the output signal OUT of the second one of the two circuits 400 bearing reference OUT2 in FIG. 9. Node 900 is coupled to an antenna ANT of transmitter 9, in this example by a radio frequency power amplifier PA.

Each of the two circuits 400 receives the control signal clk of its shift register 402.

The binary data signal received by the first circuit 400, that is, by the input In of its shift register 402, is a binary signal I, and the binary data signal received by second circuit 400, that is, by the input In of its shift register 402, is a binary signal Q. The two signals I and Q are at the same frequency Fdata. The two signals I and Q define, for example, a QPSK modulation of a signal at frequency Fdata. The two signals I and Q are, for example, delivered by a circuit 902 of transmitter 9.

Transmitter 9 further comprises at least one local oscillator LO configured to deliver a periodic signal SIGLOI at frequency Fc, and a signal SIGLOQ at the same frequency Fc but in quadrature with signal SIGLOI.

In the illustrated example, transmitter 9 comprises a single oscillator LO delivering signal SIGLOI, and further comprises a circuit 904 (block “90°” in FIG. 9) configured to deliver signal SIGLOQ from signal SILOI. In another example not illustrated, transmitter 9 comprises two oscillators LO in quadrature with each other, a first one of the two oscillators delivering signal SIGLOI, and the second one of the two oscillators delivering signal SIGLOQ.

Signal SIGLOI is delivered to the first one of the two filters 400 and corresponds to the signal SIGLO delivered to each of the circuits 700 of circuit 404 of the first one of the two filters 400, and signal SIGLOQ being delivered to the second one of the two filters 400 and corresponding to the signal SIGLO delivered to each of the circuits 700 of the circuit 404 of the second one of the two filters 400. For example, signal SIGLOI is a differential signal comprising a component in phase SIGLOI+ corresponding to the signal SIGLO+ received by the transistors 810 and 820 of each circuit 700 of the first filter 400, and a component in phase opposition SIGLOI− corresponding to the signal SIGLO− received by the transistors 814 and 818 of each circuit 700 of the first filter 400, and, similarly, signal SIGLOQ is a differential signal comprising a component in phase SIGLOQ+ corresponding to the signal SIGLO+ received by the transistors 810 and 820 of each circuit 700 of the second filter 400, and a component in phase opposition SIGLOQ− corresponding to the signal SIGLO− received by the transistors 814 and 818 of each circuit 700 of the second filter 400.

According to an embodiment, frequency Fc is equal to 60 GHz, or, in other words, transmitter 9 is configured to transmit in the 60-GHz band.

Various embodiments and variants have been described. Those skilled in the art will understand that certain features of these various embodiments and variants may be combined, and other variants will occur to those skilled in the art.

In particular, those skilled in the art are capable of adapting the description made hereabove to the case where the levels corresponding to the respective binary states ‘1’ and ‘0’ of a binary signal are inverted with respect to what has been described or to the case where power supply voltage Vdd is negative with respect to reference voltage GND, which is in practice also a power supply voltage.

Further, those skilled in the art can adapt the description made hereabove to other values of integers Q or INT or N or min or OSR or other impulse responses h(t). Preferably, when the oversampling rate OSR is not equal to 4, the latter is equal to 2n, with n being an integer greater than 2. However, the provided solution may be implemented with OSR equal to 2, for example, when it is not necessary to comply with the constraints indicated at the beginning as concerns the transmission power and, in this case, the provided solution always has a hardware implementation simpler and less bulky than the solution than the known solution disclosed in relation with FIG. 3.

Further, those skilled in the art will be capable of implementing circuits 408 and 702 with a single adder network implementing, for example, an impedance matching function, this network then corresponds to, for example, circuit 702 described in relation to FIG. 8 having the outputs 701 of all the circuits 700 of all the circuits 406i connected thereto. In other words, those skilled in the art can provide a single circuit 702 common to all circuits 404 and configured to deliver signal OUT directly, this single circuit 702 then corresponds to the circuit 408 described in relation to FIG. 4, 5, or 6.

Finally, the practical implementation of the described embodiments and variations is within the abilities of those skilled in the art based on the functional indications given herein above.

In particular, those skilled in the art can select the values of integers P or N or INT or min enabling it to obtain an impulse response of filter 400 for which the error with an ideal impulse response h(t) remains lower than a maximum target error. Further, those skilled in the art are capable of providing other examples of implementations of circuit 404 or of circuits 406i or of circuits 700 or of circuit 702 which enable device 400 to operate as described in relation to FIG. 4, the implementations of these circuits are not limited to those described in relation to FIGS. 7 and 8.

Further, those skilled in the art will be capable of implementing the described circuits, for example, in view of the frequencies of the considered signals, the transmission lines allowing the propagation of these signals. For example, those skilled in the art will be capable of implementing the transmission lines to distribute signals SIGLO+ and SIGLO− to circuits 406i or 700.

What is claimed is:

1. A radio frequency transmitter comprising a filtering circuit, the filtering circuit comprising:
a shift register comprising a binary input and N number of binary outputs, N being an integer greater than or equal to M, M being an integer greater than or equal to 2, each binary output having an index identifier ranging from o to N−1, the shift register configured to:
receive a binary data signal at a first frequency on the binary input, and
implement shifts on the binary outputs at a second frequency equal to the first frequency multiplied by M, the shift register being a series to parallel shift register;
a first circuit implemented as a function of N number of coefficients, the first circuit configured to, for each non-zero coefficient of the N number of coefficients, deliver a respective analog signal determined by the associated coefficient and a binary state of a respective output; and
an adder circuit configured to deliver an analog output signal at an output of the filtering circuit, the analog output signal being equal to the sum of the respective analog signal for each non-zero coefficient of the N number of coefficients.

2. The radio frequency transmitter of claim 1, wherein the coefficients are determined by an impulse response of an interpolation filter of a raised cosine type.

3. The radio frequency transmitter of claim 1, wherein the shift register comprises N synchronous latches controlled by a clock signal at a third frequency equal to the first frequency multiplied by M/2, the N synchronous latches coupled in series by alternating latches active on a first level of the clock signal and latches active on a second level of the clock signal, the binary outputs corresponding to outputs of the N synchronous latches.

4. The radio frequency transmitter of claim 3, wherein the shift register further comprises a synchronous D-type flip-flop having a data input coupled to a series input of the shift register, wherein a synchronization input of the synchronous D-type flip-flop is configured to receive the clock signal, and an output of the synchronous D-type flip-flop is coupled to a data input of the first one of the N synchronous latches.

5. The radio frequency transmitter of claim 1, wherein for the index identifier ranging from 0 to N−1, each corresponding coefficient is equal to an associated second coefficient with a second index identifier (p) equal to the corresponding index identifier plus a minimum constant value, the minimum constant value being an integer greater than or equal to zero, wherein each second coefficient (Dp) is determined using the formula
$$Dp = B p - {Σ}_{j = p - M + 1}^{j = p - 1} Dj ,$$
where j is an integer index, Dj is zero when j is negative, and Bp is a third coefficient of index p, and wherein each third coefficient (Bp) is determined using the formula Bp=h((2*p−P+1)/(2*M)) where h(t) is normalized and centered on t=0, and P is an odd integer greater than N.

6. The radio frequency transmitter of claim 1, wherein the shift register comprises N number of synchronous D-type flip-flops controlled by a clock signal at the second frequency, the N number of synchronous D-type flip-flops being series-connected, and the binary outputs corresponding to outputs of the N number of synchronous D-type flip-flops.

7. The radio frequency transmitter of claim 1, wherein the shift comprises N number of synchronous D-type flip-flops controlled by a clock signal at a third frequency equal to the first frequency multiplied by M/2, the N number of synchronous D-type flip-flops being coupled in series by flip-flops alternately arranged to be active on the rising edges of the clock signal and active on the falling edges of the clock signal, and the binary outputs corresponding to outputs of the N number of synchronous D-type flip-flops.

8. The radio frequency transmitter of claim 1, wherein, for each non-zero coefficient, the first circuit comprises K number of identical elementary circuits, K being equal to an absolute value of the rounding to an integer value of the product of the coefficient and an identical integer for all coefficients, each identical elementary circuit having an associated output configured to:
deliver a first analog signal in response to an associated binary output being in a first binary state and the coefficient being positive or the associated binary output being in a second binary state and the coefficient being negative; and
deliver a second signal complementary to the first signal in response to the associated binary output being in a second binary state and the coefficient being positive or the associated binary output being in a first binary state and the coefficient being negative.

9. The radio frequency transmitter of claim 8, wherein, for each coefficient, the first circuit comprises a plurality of identical elementary circuits, the first circuit further comprising a selection circuit configured to:
select, for each coefficient, T number of elementary circuits from among the plurality of identical elementary circuits, T being equal to zero for coefficients equal to zero; and
turning off the non-selected elementary circuits.

10. The radio frequency transmitter of claim 8, wherein each elementary circuit is configured to receive the same periodic signal such that the respective analog signal is in-phase with the periodic signal with the corresponding frequency of the periodic signal.

11. The radio frequency transmitter of claim 8, wherein a respective output of each elementary circuit comprises a first output node and a second output node, each elementary circuit comprising:
a first metal-oxide semiconductor (MOS) transistor coupling a reference node to a first inner node;
a second MOS transistor coupling the reference node to a second inner node, wherein, for each non-zero coefficient and each of the K number of elementary circuits, the first MOS transistor and the second MOS transistor are controlled from a corresponding binary output, in-phase opposition with respect to each other;
a third MOS transistor coupling the first inner node to the first output node, the third MOS transistor having a gate configured to receive the periodic signal;
a fourth MOS transistor coupling the first inner node to the second output node, the fourth MOS transistor having a gate configured to receive an in-phase opposition signal to the periodic signal;
a fifth MOS transistor coupling the second inner node to the first output node, the fifth MOS transistor having a gate configured to receive the in-phase opposition signal; and
a sixth MOS transistor coupling the second inner node to the second output node, the sixth MOS transistor having a gate configured to receive the periodic signal.

12. The radio frequency transmitter of claim 8, wherein the filtering circuit is a first filtering circuit, the radio frequency transmitter further comprising a second filtering circuit, wherein each of the first two filtering circuits is configured to deliver a respective output signal to a same node coupled to an antenna of the radio frequency transmitter, wherein the input of the shift register of the first filtering circuit receives a first binary data signal at the first frequency, and wherein the input of the shift register of the second filtering circuit receives a second binary data signal at the first frequency.

13. The radio frequency transmitter of claim 12, further comprising a local oscillator configured to deliver a first periodic signal and a second periodic signal in quadrature with the first periodic signal, a periodic signal received by the elementary circuit of the first filtering circuit is the first periodic signal, and wherein a periodic signal received by the elementary circuit of the second filtering circuit is the second periodic signal.

14. The radio frequency transmitter of claim 1, wherein the radio frequency transmitter is configured to transmit in the 60-GHz band.

15. A method, comprising:
receiving a binary data signal at a first frequency on a binary input of a shift register, the shift register being a series to parallel shift register of a filtering circuit of a radio frequency transmitter;
implementing shifts on N number of binary outputs of the shift register at a second frequency equal to a first frequency multiplied by M, N being an integer greater than or equal to M, M being an integer greater than or equal to 2, each binary output having an index identifier ranging from 0 to N−1;
delivering, by a first circuit of the filtering circuit implemented as a function of N number of coefficients, for each non-zero coefficient of the N number of coefficients, a respective analog signal determined by the associated coefficient and a binary state of a respective output; and
delivering, by an adder circuit of the filtering circuit, an analog output signal at an output of the filtering circuit, the analog output signal being equal to the sum of the respective analog signal for each non-zero coefficient of the N number of coefficients.

16. The method of claim 15, wherein the coefficients are determined by an impulse response of an interpolation filter of a raised cosine type, and wherein the shift register comprises N synchronous latches controlled by a clock signal at a third frequency equal to the first frequency multiplied by M/2, the N synchronous latches coupled in series by alternating latches active on a first level of the clock signal and latches active on a second level of the clock signal, the binary outputs corresponding to outputs of the N synchronous latches.

17. The method of claim 16, wherein the shift register further comprises a synchronous D-type flip-flop having a data input coupled to a series input of the shift register, wherein a synchronization input of the synchronous D-type flip-flop is configured to receive the clock signal, and an output of the synchronous D-type flip-flop is coupled to a data input of the first one of the N synchronous latches.

18. The method of claim 15, wherein the shift register comprises N number of synchronous D-type flip-flops controlled by a clock signal at the second frequency, the N number of synchronous D-type flip-flops being series-connected, and the binary outputs corresponding to outputs of the N number of synchronous D-type flip-flops.

19. The method of claim 15, wherein the shift comprises N number of synchronous D-type flip-flops controlled by a clock signal at a third frequency equal to the first frequency multiplied by M/2, the N number of synchronous D-type flip-flops being coupled in series by flip-flops alternately arranged to be active on the rising edges of the clock signal and active on the falling edges of the clock signal, and the binary outputs corresponding to outputs of the N number of synchronous D-type flip-flops.

20. The method of claim 15, wherein, for each non-zero coefficient, the first circuit comprises K number of identical elementary circuits, K being equal to an absolute value of the rounding to an integer value of the product of the coefficient and an identical integer for all coefficients, the method further comprising, for each identical elementary circuit having an associated output:
delivering a first analog signal in response to an associated binary output being in a first binary state and the coefficient being positive or the associated binary output being in a second binary state and the coefficient being negative; and
delivering a second signal complementary to the first signal in response to the associated binary output being in a second binary state and the coefficient being positive or the associated binary output being in a first binary state and the coefficient being negative.

21. A filtering circuit, comprising:
a shift register comprising a binary input and N number of binary outputs, N being an integer greater than or equal to M, M being an integer greater than or equal to 2, each binary output having an index identifier ranging from 0 to N−1, the shift register configured to:
receive a binary data signal at a first frequency on the binary input, and
implement shifts on the binary outputs at a second frequency equal to the first frequency multiplied by M, the shift register being a series to parallel shift register;
a first circuit implemented as a function of N number of coefficients, the first circuit configured to, for each non-zero coefficient of the N number of coefficients, deliver a respective analog signal determined by the associated coefficient and a binary state of a respective output; and
an adder circuit configured to deliver an analog output signal at an output of the filtering circuit, the analog output signal being equal to the sum of the respective analog signal for each non-zero coefficient of the N number of coefficients.
